(19) United States
(12) Patent Application Publication
(10) Pub. No.: US 2005/0248259 A1
(43) Pub. Date: Nov. 10, 2005

(54) Bent lead light emitting diode device having a heat dispersing capability

(76) Inventor: Roger Chang, Taoyuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/841,531

(22) Filed: May 10, 2004

(51) Int. Cl. H01L 29/22

(52) U.S. Cl. 313/498

(57) ABSTRACT

A bent lead light emitting diode device having a heat dissipating capability mainly has a flat chip seat, a horizontal and vertical separation layers, at least two bent leads, at least one light emitting diode chip and a transparent cover. A tapered recess is defined in an upper flat surface of the chip seat where the light emitting diode chip is mounted. The bent leads arranged around the chip seat are separated from the chip seated by the horizontal and vertical separation layers and connected to the chip wire bondings. When the bent lead light emitting diode device is operating, heat is conducted away by the chip seat. The chip seat is flat so the horizontal and vertical separation layers between the chip seat and the bent leads do not have to be a specific shape.

### BACKGROUND OF THE INVENTION

1. Field of the Invention

The present invention relates to a light emitting diode device package and more particularly to a bent lead light emitting diode device having a heat dispersing capability.

2. Description of Related Art

With reference to FIG. 3, a conventional LED package includes a chip seat (20), molded encapsulant (26), a light emitting diode chip (23), leads (25), wire bondings (24) and a transparent cover (27). The chip seat (20) is stepped and has a shoulder (28), a neck (21) and a chip recess (22). The molded encapsulant (26) is formed around the chip seat (20) and generally conforms to the shape of the chip seat (20). A separated step-shaped mold (not shown) is required to form the molded encapsulant (26) around the chip seat (10). The leads (25) are arranged around the chip seat (20) and conform to the step shape of the chip seat (20) so each lead is bent to a Z-shape and is attached to the encapsulant (26) corresponding to the shoulder (28). The chip recess (22) is defined in the neck (21), and the light emitting diode chip (23) is mounted in the chip recess (22). Wire bondings (24) connect the chip (23) to the leads (25). The transparent cover (27) is attached to the molded encapsulant (26) to cover the chip recess (22). The chip recess (22) may be filled with a transparent material (29).

The forgoing LED package has a heat dissipating capability since the chip seat is metallic that conducts heat away from the light emitting diode chip. However, the stepped chip seat and molded encapsulant are formed in separated molds, and mounting the Z-shaped bent leads on the encapsulant is difficult. Therefore, the LED package having such a structure is not easy to fabricate.

To overcome the shortcomings, the present invention provides a new bent lead light emitting diode device having a heat dissipating capability to mitigate or obviate the aforementioned problems

### SUMMARY OF THE INVENTION

The main objective of the invention is to provide a bent lead light emitting diode (LED) device having a heat dissipating capability that is fabricated easily and has low fabricating cost.

Other objectives, advantages and novel features of the invention will become more apparent from the following detailed description when taken in conjunction with the accompanying drawings.

### BRIEF DESCRIPTION OF THE DRAWINGS

FIG. 1 is a side view in partial section of a first embodiment of a light emitting diode device in accordance with the present invention;

FIG. 2 is a side view in partial section of a second embodiment of a light emitting diode device in accordance with the present invention; and

FIG. 3 is a side view in partial section of a conventional semiconductor package in accordance with the prior art.

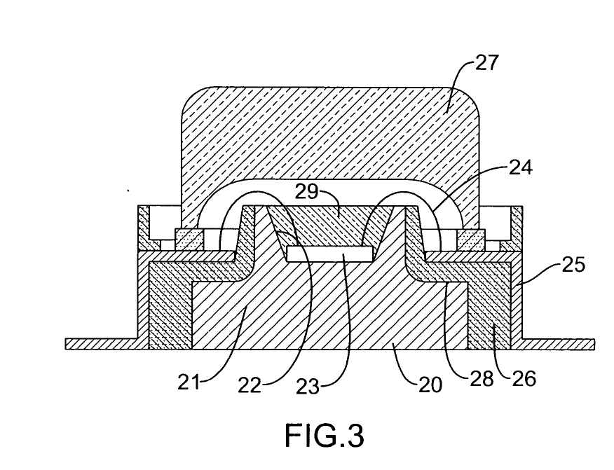

### DETAILED DESCRIPTION OF THE PREFERRED EMBODIMENT

A light emitting diode (LED) device in accordance with the present invention relates to a bent lead LED device that has a simple heat dissipating device and is fabricated easily.

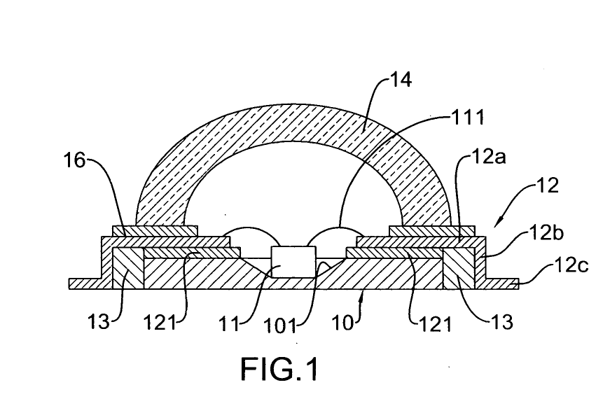

With reference to FIG. 1, the bent lead LED device in accordance with the present invention includes a flat chip seat (10), at least one light emitting diode chip (11), a horizontal separation layer (121), a vertical separation layer (13), at least two bent leads (12), wire bondings (111), a transparent cover (14) and bonding material (16).

The flat chip seat (10) has an upper flat surface (not numbered), lower flat surface (not numbered), sides (not numbered) and a tapered recess (101). The tapered recess (101) is defined in the upper flat surface. For illustrative purposes, the embodiment described has a single light emitting diode chip (11) mounted in the tapered recess (101).

The horizontal separation layer (121) has an outer edge (not numbered) and an upper surface (not numbered) and is mounted on the upper flat surface of the flat chip seat (10) around the tapered recess (101). The outer edge of the horizontal separation layer (121) is flush with the sides of the flat chip seat (10).

The vertical separation layer (13) has a top edge (not numbered), a bottom edge (not numbered) and an outside surface (not numbered) and is mounted around the sides of the flat chip seat (10) and the outer edge of the horizontal separation layer (121). The top edge is flush with the upper surface of the horizontal separation layer (121), and the bottom edge is flush with the lower flat surface of the flat chip seat (10).

The at least two bent leads (12) are arranged around the chip seat (10). Each of the bent leads (12) is formed in a Z-shape and has a top horizontal arm (12a), a vertical arm (12b) and a bottom horizontal arm (12c). The top horizontal arm (12a) is attached to the horizontal separation layer (121) and the upper edge of the vertical separation layer (13). The vertical arm (12b) is attached to the outside surface of the vertical separation layer (13). The bottom horizontal arm (12c) has a bottom edge (not numbered) that is flush with the lower flat surface of the chip seat (10).

Wire bondings (111) connect the light emitting diode chip (11) respectively to the top horizontal arms (12b) of the bent leads (12).

The transparent cover (14) has a bottom edge (not numbered) and is attached to the top horizontal arms (12a) of the bent leads (12) to cover the tapered recess (101).

Bonding material (16) is applied to the bottom edge of the transparent cover (14) and the top horizontal arm (12b) of the bent leads (12) to securely attach the transparent cover (14) to the bent leads (12).

Since the bottom horizontal arm (12c) is flush with the lower flat surface of the chip seat (10), the LED is packaged as a surface mounted device (SMD). The chip seat (10) is flat so the bent lead (12) can be attached directly to the upper flat surface of the chip seat (10).

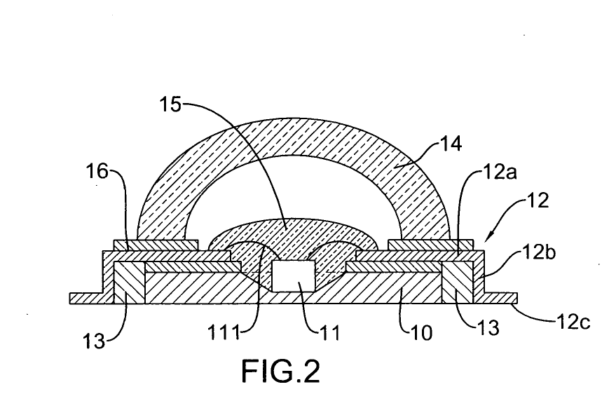

With reference to FIG. 2, a second embodiment of the LED device in accordance with the present invention is similar to the first embodiment, but the chip recess (101) is further filled with transparent encapsulant (15) to protect the light emitting diode chip (11). The transparent encapsulant (15) may further comprise diffusing material. The brightness of light from the light emitting diode chip (11) passing through the transparent encapsulant (15) can be diffused throughout the field of view. The light emitting diode chip (11) can be red, blue, green, etc. Further, multiple light emitting diode chips (11) may be mounted in the chip recess, wherein the multiple light emitting diode chips may be the same light color or different light color to mix another light color.

When the forgoing LED device is driven, heat is produced by the light emitting diode chip (11). The light emitting diode chip (10) is directly mounted on the chip seat (10) so heat is conducted away from the chip (11) by the chip seat (10). Since the chip seat (10) is flat, the present invention does not require specific molds to form the vertical separation layer. Therefore, the present invention has advantages of being easy to fabricate, having low fabrication cost, etc.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A bent lead light emitting diode device having a heat dissipating capability, comprising:
a chip seat made of metal and having an upper flat surface, a lower flat surface, sides and a tapered recess defined in the top flat surface;
a horizontal separation layer being mounted on the upper flat surface of the flat chip seat around the tapered recess and having an outer edge flush with the sides of the flat chip seat and an upper surface;
a vertical separation layer being mounted around the sides of the flat chip seat and the outer edge of the horizontal separation layer and having a top edge flush with the upper surface of the horizontal separation layer, a bottom edge flush with the lower flat surface of the flat chip seat and an outside surface;
at least one light emitting diode chip mounted in the tapered recess;
at least two bent leads arranged around the chip seat, wherein each bent lead has
a top horizontal arm attached to the horizontal separation layer and the upper edge of the vertical separation layer;
a vertical arm attached to the outside surface of the vertical separation layer; and
a bottom horizontal arm flush with the lower flat surface of the chip seat;
multiple wire bondings connecting the light emitting diode chip respectively to the at least two bent leads; and
a transparent cover attached on the top horizontal arms to cover the tapered recess in the chip seat.

2. The bent lead light emitting diode device as claimed in claim 1, wherein the tapered recess is filled with transparent encapsulant.

3. The bent lead light emitting diode device as claimed in claim 1, wherein one light emitting diode chip is mounted in the tapered recess.

4. The bent lead light emitting diode device as claimed in claim 2, wherein one light emitting diode chip is mounted in the tapered recess.

5. The bent lead light emitting diode device as claimed in claim 1, wherein multiple light emitting diode chips with a same color are mounted in the tapered recess.

6. The bent lead light emitting diode device as claimed in claim 2, wherein multiple light emitting diode chips with a same light color are mounted in the tapered recess.

7. The bent lead light emitting diode device as claimed in claim 2, wherein multiple light emitting diode chips respectively of different colors are mounted in the tapered recess and the transparent encapsulant further comprises diffusing material.
